(19) United States
(12) Patent Application Publication
(10) Pub. No.: US 2014/0167241 A1
(43) Pub. Date: Jun. 19, 2014

(54) SEMICONDUCTOR DEVICE

(71) Applicant: Kabushiki Kaisha Toshiba, Tokyo (JP)

(72) Inventor: Nobutaka MATSUOKA, Hyogo-ken (JP)

(21) Appl. No.: 13/915,030

(22) Filed: Jun. 11, 2013

(30) Foreign Application Priority Data
Dec. 18, 2012 (JP) 2012-275700

(51) Int. Cl. H01L 23/48

(52) U.S. Cl. CPC H01L 23/48
USPC 257/690; 438/121

(57) ABSTRACT

A semiconductor device includes a resin package, a semiconductor element, a sealing resin, and a metal terminal. The sealing resin is filled into the resin package to seal the semiconductor element and the insulating substrate. The metal terminal is extended from the inside of the resin package to the outside of the resin package and electrically is connected to the semiconductor element inside of the resin package. The metal terminal has a busbar mounting portion provided with a hole for a bolt to pass therethrough and configured by a parallel planar body on the top surface of the resin package including the resin top plate, a lead portion connected to the busbar mounting portion extended in a direction perpendicular to the surface of the heat sink, and a spring structure having a bias in a direction perpendicular to the surface of the resin package in the busbar mounting portion.

### CROSS-REFERENCE TO RELATED APPLICATION

This application is based upon and claims the benefit of priority from Japanese Patent Application No. 2012-275700, filed Dec. 18, 2012; the entire contents of which are incorporated herein by reference.

### FIELD

The embodiments described herein relate generally to a semiconductor device.

### BACKGROUND

A power semiconductor device includes semiconductor elements such as an Insulated Gate Bipolar Transistor (IGBT) for high-power applications or a Metal Oxide Semiconductor Field Effect Transistor (MOSFET), the elements of which are sealed in a silicon-based resin to form a packaged device. The outer surface of the resin is covered to seal the package, or seal a terminal holder made of resin that will become the support member of the power terminals and the signal terminals for the packaged device. The cover is formed so as to cover the outer surface of the resin.

Furthermore, a terminal holder supports the power terminals or the signal terminals of the packaged device so that the power terminals or the signal terminals that are electrically connected to the various electrodes of the semiconductor element are extended from the inside to the outside of the resin. In one case, the power terminals or the signal terminals extend from the inside to the outside of the resin by passing through an opening of the terminal holder. The terminal holder is secured to the outer frame of the resin package by an epoxy-based resin provided over the silicon-based resin. When a high-power semiconductor device is used in high-power control circuits or the like, a portion of the power terminal is screwed to a busbar using a bolt or a nut. A large current may flow via the busbar between the high-power semiconductor device and the power control circuit. For the purpose of this configuration, the power terminals, and the like of the high-power semiconductor device may be stressed, vibrated or the like via the busbar. As a result, inside of the resin package, the location where the power terminal is secured to the power device with a solder may fail, causing poor, intermittent or no conductivity. Alternately, the screw of the power terminal and the busbar may loosen, posing a risk of poor, intermittent or no conductivity.

### DESCRIPTION OF THE DRAWINGS

FIG. 1 is a schematic cross-sectional view of a semiconductor device according to a first embodiment.

FIG. 2 is a schematic cross-sectional view of a semiconductor device according to a second embodiment.

FIG. 3 is a schematic cross-sectional view of a semiconductor device according to a third embodiment.

FIG. 4 is a schematic cross-sectional view of a semiconductor device according to a fourth embodiment.

### DETAILED DESCRIPTION

Embodiments provide a semiconductor device that alleviates stress or vibration on the power terminals.

In general, embodiments will be explained below with reference to the drawings. The drawings used in the explanation of the present embodiment are schematic for the purpose of simplifying the explanation, so the shape, dimension, magnitude relation and so forth of each element in the drawings do not necessarily represent the actual ones; appropriate modifications are possible as long as the modifications are carried out within the scope that achieves the effect of the present embodiment.

A semiconductor device of the present embodiment includes a resin package, a semiconductor element, sealing resins, and metal terminals. The resin package has a heat sink, a casing along the edge of the surface of the heat sink and surrounding the top of the surface of the heat sink, and a resin top plate separated from the heat sink and provided over the heat sink. The semiconductor element is positioned over the heat sink via an insulating substrate. Sealing resins are filled into the casing to seal the semiconductor element and the insulating substrate therein. The metal terminal extends from the inside of the casing to the outside of the casing and is electrically connected to the semiconductor element inside of the casing. The metal terminal has a busbar mounting portion formed by a parallel planar body on top of the resin package containing the resin top plate and is provided with a hole for a bolt to pass through; a lead portion connected to the busbar mounting portion extended in a direction perpendicular to the top surface of the casing; and a spring structure to provide bias in a direction perpendicular and away to the top surface of the resin package in the busbar mounting portion.

### First Embodiment

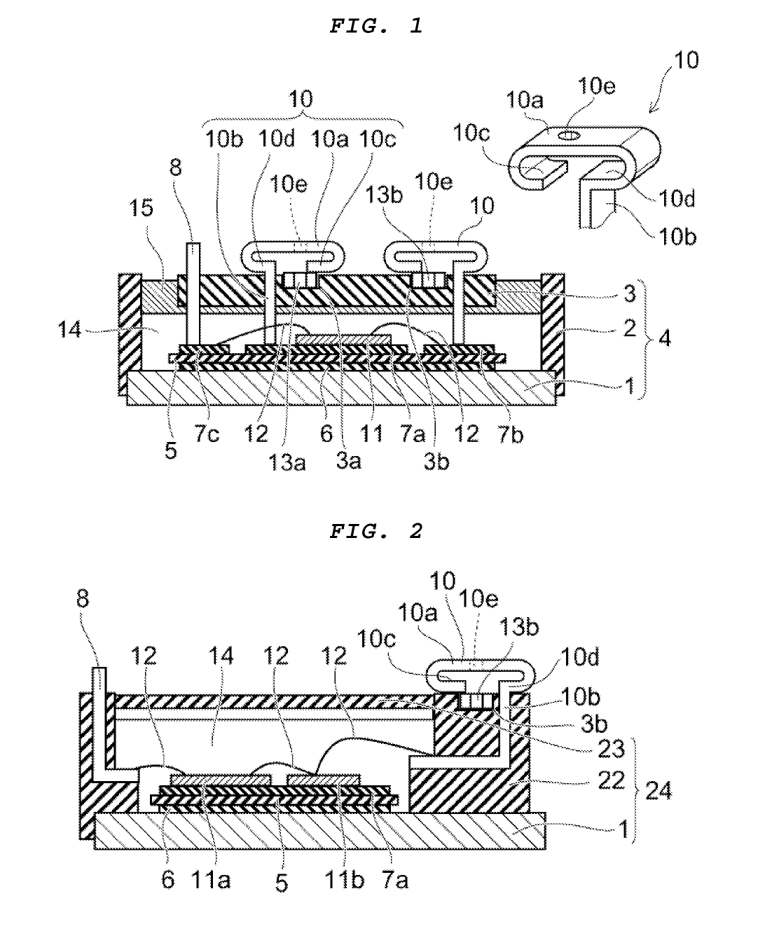

The semiconductor device according to the first embodiment will be explained using FIG. 1. FIG. 1 is a schematic cross-sectional view of the semiconductor device according to the first embodiment. The drawing, along with the schematic cross-sectional view, shows an enlarged perspective view of a substantial portion of a power terminal 10.

The semiconductor device according to the first embodiment includes a casing 4, a semiconductor element 11, a silicon gel 14 (a sealing resin), an epoxy resin 15 (a sealing resin), and a power terminal 10 (a metal terminal) and a signal terminal 8 (a metal terminal).

The casing 4 includes a heat sink 1, a resin case 2, and a terminal holder 3 (a resin top plate). The heat sink 1 may comprise copper or ceramic. The resin case 2 surrounds the top surface of the heat sink 1 along the perimeter of the surface of the heat sink 1, to form, in conjunction with the heat sink, a receptacle volume. The resin case 2 is made of, for example, polybutylene terephthalate (PBT) or polyphenylene sulfide (PPS). The terminal holder 3 is in a plate shape and is provided over, and separate from, the heat sink 1. As will be explained herein, a silicon gel 14 is filled into the receptacle volume bounded by the resin case 2, and epoxy resin 15 is filled over the silicon gel 14. The terminal holder 3 is secured to the resin case 2 with the epoxy resin 15. The terminal holder 3 is made of, for example, PBT or PPS.

The semiconductor element 11 is positioned over the heat sink 1 and in the receptacle volume via an insulating substrate 5 provided therebetween. The semiconductor element 11 is a semiconductor element, such as a thyristor, a diode, an IGBT or a MOSFET. In the semiconductor device of the present embodiment, the semiconductor element 11 will be explained in the case of a single element; however, in practice, multiple semiconductor elements or a combination thereof may also be packaged together. In the present embodiment, the connection of a semiconductor element 11 using a MOSFET as an example will be discussed.

The insulating substrate 5 has a metal film 6 covering at least the majority of back surface thereof. The metal layer 6 is made of, for example, copper. The insulating substrate 5 is secured to the top of the heat sink 1 by a solder film 6. The insulating substrate 5 has metal wiring patterns 7a to 7c on the surface thereof. The metal wiring pattern is, for example, copper features. The semiconductor element 11 is installed over the metal wiring pattern 7a via a drain electrode of the back surface of the semiconductor element 11. A source electrode and a gate electrode are provided on the surface of the semiconductor element 11. The power terminals 8, 10 extend through the terminal holder 3 and a silicon gel and terminate at one end thereof in electrical contact with selected portions of the metal wiring pattern 7.

The end of the power terminal 10 for the drain electrode of the semiconductor device is electrically connected to the metal wiring pattern 7a. Thus, the power terminal 10 electrically connects to the drain electrode of the semiconductor element 11 via the metal wiring pattern 7a. The power terminal 10 for the drain electrode includes a busbar mounting portion 10a for connection to an external busbar, a lead portion 10b which extends from busbar mounting portion to metal wiring pattern 7a, and two folded portions 10c and 10d provided to elastically space busbar portion 10a from terminal holder 3. The power terminal 10 for the drain electrode is made of, for example, copper.

One end of the lead portion 10b is electrically connected to the metal wiring pattern 7a, which extends in a direction generally perpendicular to the surface of the heat sink 1, and passes through the terminal holder 3 via an opening therein. That is, the power terminal 10 for the drain electrode is extended from within the resin package 4 to the exterior of the resin package.

The busbar mounting portion 10a of the metal terminal 10 is formed by a generally planar body over, and generally parallel to, the adjacent outer surface of the terminal holder 3. The busbar mounting portion 10a is provided with a hole 10e for a bolt to pass through or a screw to be secured in. By folding one end of the busbar mounting portion 10a, the busbar mounting portion 10a has the folded portion 10c facing the busbar mounting portion 10a. Similarly, the busbar mounting portion 10a has the folded portion 10d facing the busbar mounting portion 10a at the other end, which is the opposite side of the one end. The folded portions 10c, 10d, space the busbar mounting position 10a from the terminal holder, and also provide an elastic spring or bias action to accommodate pushing force perpendicular to the top or face of terminal holder 3 or vibration on busbar portion 10a.

Thus the busbar mounting portion 10a is formed at the opposite end of power terminal 10 from the end of lead portion 10b contacting metal wiring pattern 7b. The busbar mounting portion 10a is spaced from the outer side of the terminal holder 3 via the two folded portions 10c and 10d. The folded portions 10c and 10d are provided to function as spring structures accommodating vibration or force in a direction perpendicular to the top surface of the terminal holder 3 (a direction perpendicular to the top surface of the resin package).

A recess 3a is provided on the outer surface of the terminal holder 3 on the opposite side of the heat sink 1. Provided inside of this recess 3a is a threaded nut 13a for securing the power terminal 10 for the drain electrode to the busbar using a bolt. The recess 3a is formed so that the center of the recess 3a is aligned, in a direction perpendicular to the heat sink 1, with the center of the hole 10e provided on the busbar mounting portion 10a of the power terminal 10. The recess 3a has an outline the same as that of the nut 13a. In this way, the nut 13a fits inside of the recess 3a and is secured so that the nut does not rotate during tightening of a bolt therein. The folded portion 10c of power terminal 10 is formed so that the tip of the folded portion 10c that is folded under the busbar mounting portion 10a of the power terminal 10 is sandwiched between the busbar mounting portion 10a and the nut 13a. Although not shown in the drawing, the busbar can be electrically connected to the power terminal 10 for the drain electrode by tightening a bolt, passing through the hole 10e of the busbar mounting portion 10a of the power terminal 10 and the hole of the busbar, into the nut 13a not shown in the drawing.

One end of the power terminal 10 for the source electrode is electrically connected to the metal wiring pattern 7b on top of the insulating substrate 5. The power terminal 10 for the source electrode has exactly the same configuration as the power terminal 10 for the drain electrode. Additionally, in exactly the same way, the busbar mounting portion 10a is arranged, extending from the inside of the casing 4 to the outside of the casing 4, and a nut 13b is provided inside of the recess 3b formed on the outer surface of the terminal holder 3. Similarly, to the power terminal 10 for the drain electrode, the power terminal 10 for the source electrode can be electrically connected to a busbar, not shown in the drawing, by a bolt, (not shown in the drawing) extending through the busbar mounting portion 10a and secured into the nut 13b.

The metal wiring pattern 7b is electrically connected to the source electrode of the semiconductor element 11 by a bonding wire 12. In this way, the power terminal 10 for the source electrode is electrically connected to the source electrode of the semiconductor element 11 via the metal wiring pattern 7b and the bonding wire 12.

One end of the signal terminal 8 is electrically connected to the metal wiring pattern 7c on top of the insulating substrate 5. The signal terminal 8 extends through the terminal holder 3 similar into the power terminal 10 from the inside of the casing 4 to the outside of the casing 4. The metal wiring pattern 7c is electrically connected to the gate electrode of the semiconductor element 11 by the bonding wire 12. In this way, the signal terminal is electrically connected to the gate electrode of the semiconductor element 11 via the metal wiring pattern 7c and the bonding wire 12. That is, the connection to gate electrode extends to the outside of the casing 4 by the signal terminal 8.

By filling the casing 4 with a silicon gel 14, the semiconductor element 11, the insulating substrate 5, the bonding wire 12, the lead portion 10b of the power terminal 10 for the drain electrode, the lead portion 10b of the power terminal 10 for the source electrode, and the signal terminal 8 are sealed by the silicon gel 14. Furthermore, the terminal holder 3 is secured to the resin case 2 by providing the epoxy resin 15 over of the silicon gel 14. Moreover, the silicon gel 14 inside of the casing 4 is sealed by the epoxy resin 15.

In the semiconductor device according to the present embodiment, the semiconductor element 11, and adjacent components are sealed by using the silicon gel 14 and the epoxy resin 15. However, when using a low stress silicon gel having a smaller stress with respect to the semiconductor element 11 than the epoxy resin 15, the semiconductor element 11, and the like can be sealed inside of the casing 4 only by the low stress silicone gel, and the terminal holder 3 is secured to the resin case 2 using the resin 15. Thus, motion of the resin case is isolated from the semiconductor element 11 by the intervening silicon gel 14.

In the semiconductor device according to the present embodiment, the power terminal 10 for the drain electrode and the source electrode includes the busbar mounting portion 10a, the lead portion 10b, and the folded portions 10c and 10d. The folded portions 10c and 10d are provided to either side of the mounting portion 10a. For this reason, by securing the busbar mounting portion 10a to the busbar by the bolt and a nut 13, the folded portions 10c and 10d of both ends function as a spring which when compressed provides a bias in a direction perpendicular to the top surface of the terminal holder 3. That is, the folded portions 10c and 10d are spring structures. Therefore, the power terminal 10 has the busbar mounting portion 10a, the lead portion 10 and the spring structure.

When the power terminal 10 for the drain electrode and the source electrode of the semiconductor device is electrically secured to the busbar by the bolt and the nut 13, a vibration from the busbar is propagated to the power terminal 10 of the semiconductor device. The lead portion 10b of the power terminal 10 and the metal wiring patterns 7a and 7b on top of the insulating substrate 5 are electrically connected by solder. For this reason, when a vibration is transmitted to the power terminal 10, cracks may occur at the solder joint, causing a conduction defect or failure.

In the semiconductor device of the present embodiment, however the power terminal 10 for the drain electrode and the source electrode as has been explained above has the folded portions 10c and 10d functioning as a spring by the configuration including the busbar mounting portion 10a, the lead portion 10b, and the folded portions 10c and 10d. For this reason, the vibration that has been propagated to the power terminal 10 from the busbar is mitigated by the folded portions 10c and 10d. As a result, the propagation of the vibration is attenuated or eliminated toward the soldered connection of the lead portion 10b of the power terminal 10 and the metal wiring patterns 7a and 7b of the insulating substrate 5, so that the resulting failure of the solder joint in the semiconductor device of the present embodiment is substantially reduced or eliminated.

Furthermore, the tips of the folded portions 10c or 10d of the power terminal 10 extend between the busbar mounting portion 10a and the nuts 13a or 13b, so that the folded portions 10c and 10d enable the busbar mounting portion 10 to function as a lock washer. In other words, the tightening between the bolt and the nut 13 is better secured as a result of the bias of the folded portions 10c and 10d in a direction perpendicular to, and away from, the terminal holder. As a result, even when vibration is transmitted to the power terminal 10 from the busbar, the loosening of the connection between the bolt and the nuts 13a and 13b in the busbar mounting portion 10a of the power terminal 10 is suppressed. Therefore, the occurrence of the conduction defect between the power terminal 10 and the busbar which occurs when the busbar separated from a power terminal is suppressed.

### Second Embodiment

A semiconductor device according to the second embodiment will be explained using FIG. 2. FIG. 2 is a schematic cross-sectional view of the semiconductor device according to the second embodiment. The drawing shows an enlarged schematic cross-sectional view of a portion of the power terminals 10 the same elements as those described in the first embodiment will use the same reference numbers or symbols, and a duplicative explanation thereof will be omitted. The explanation will mainly concentrate on the differences as compared to the first embodiment.

In the semiconductor device of the present embodiment, the lead portion 10b of the power terminal 10 for the source electrode is embedded inside of a casing 22 of resin and is made of metal with the body being integrated within the casing. The portion of the power terminal 10 for the source electrode extending outwardly of the package has the same configuration as that in the first embodiment: The power terminal has a busbar mounting portion 10a, a lead portion 10b, and two folded portions 10c and 10d on either side of the busbar mounting portion 10a. The power terminal 10 for the source electrode of the present embodiment has the same shape as the power terminal 10 for the source electrode according to the first embodiment, except for the shape in the lead portion 10b extending through casing 22.

The casing 22 is formed to have a thicker wall, on one side thereof, than the casing according to the first embodiment to enable incorporation of the lead portion 10b of the power terminal 10 therein. The casing 22 has a top surface at the opposite side thereof from the heat sink. A recess 3b for accommodating a nut 13b is formed on top of this surface, similar to the recesses 3a and 3b that are formed on the top surface of the terminal holder 3 according to the first embodiment.

The busbar mounting portion 10a of the power terminal 10 for the source electrode is provided on top of the surface of the casing 22 via the two folded portions 10c and 10d, similarly to that in the first embodiment. The center of the hole 10e of the busbar mounting portion 10a and the center of the hole of the nut 13b provided inside of the recess 3b on top of the resin case 22 are aligned in a direction perpendicular to the surface of the heat sink 1. The tip of one end of the folded portion of the busbar mounting portion 10a extends into the space between the busbar mounting portion 10a and the nut 13b. The other end of the folded portion is connected to the top end of the lead portion 10b. The lead portion 10b is exposed inside of a resin package 24, with the inner walls of the casing 22 extending from the top surface of the casing 22 along the direction perpendicular to the heat sink 1 to an enlarged portion having a lower recess within which the heat sink 1 is received.

The enlarged portion is provided by reducing the width of the casing 22 wall between the lead portion 10b and the upper outer side of the package such that the portion of the casing 22 below the lead portion 10b has a thicker wall. The heat sink 1 having the semiconductor element 11 thereon is exposed within the perimeter of the wall of the casing 22. One end of this lead portion 10b is exposed at a ledge formed between the thinner and thicker portions of the wall of casing 22, and the source electrode located on the metal wiring pattern 7a on top of the insulating substrate 5 is electrically connected thereto with the bonding wire 12.

In this embodiment, the semiconductor element is configured by a MOSFET 11a and a MOSFET 11b electrically installed in parallel on top of the metal wiring pattern 7aon top of the insulating substrate 5. The source electrode of the MOSFET 11a and the source electrode of the MOSFET 11b are electrically connected with the bonding wire 12.

The power terminal 10 for the drain electrode, not shown in the drawing, is also formed with the lead portion 10b being built in inside of the casing 22, just like the power terminal 10 for the source electrode. The power terminal 10 for the drain electrode is also configured to have the busbar mounting portion 10a, the lead portion 10b, and two folded portions 10c and 10d on both ends, which is exactly the same as the power terminal 10 for the source electrode. The power terminal 10 for the drain electrode has one end of the lead portion 10b exposed inside of the casing 24, in the same way as the power terminal 10 for the source electrode. The exposed end is electrically connected to the metal wiring pattern 7a by a bonding wire not shown in the drawing to which the two semiconductor elements 10a and 10b are installed on top of the insulating substrate.

The signal terminal 8 is also formed by incorporating the signal terminal inside of the casing 22, as in the case with the power terminal 10 for the source electrode. One end of the signal terminal 8 is exposed inside of the resin package 24, similar to the power terminal 10 for the source electrode and the drain electrode. One end of the upper surface of signal terminal 8 exposed inside of the resin package 24 of the signal terminal 8 is electrically connected to the gate electrode of the semiconductor element 11a by bonding wire. Although omitted in the drawing, one end of the signal terminal 8 is electrically connected to the gate electrode of the semiconductor element 11b by the bonding wire. The gate electrodes of the two of the semiconductor elements 11a and 11b are drawn out of the resin package 24 by projecting the other end, which is at the opposite side of the one end previously mentioned of the signal terminal 8 to the exterior of the resin package 24.

The silicon-based resin 14 of a gel type is injected on top of the heat sink 1 surrounded by the casing 22, similar to the semiconductor device according to the first embodiment, and the insulating substrate 5, semiconductor elements 11a and 11b, the bonding wire 12, the power terminals 10 for the drain electrode and the source electrode and the signal terminal 8 are sealed by the silicon resin 14.

In the semiconductor device according to the present embodiment, the power terminals 10 and the signal terminal 8 are provided integrally within the body of the casing 22, so that the terminal holder 3 to support these terminals is not necessary. A resin cover 23 (the resin top plate) is used to seal the interior of the casing 22. The resin cover 23 is fitted to the opening portion at the top of the casing 24 so as to cover the top of the casing 22. For this reason, in the semiconductor device according to the present embodiment, the epoxy resin 15 is not necessary, which is different from the semiconductor device according to the first embodiment. The resin package 24 is configured to include the heat sink 1, the resin case 22 and the resin cover 23.

In the semiconductor device of the present embodiment, similar to the semiconductor device according to the first embodiment, the power terminals 10 for the drain electrode and the source electrode have two folded portions 10c and 10d functioning as the spring by having a configuration including the busbar mounting portion 10a, the lead portion 10b and two folded portions 10c and 10d. For this reason, vibration which would be propagated from the busbar to the power terminal 10 is mitigated or attenuated by the folded portions 10c and 10d. As a result, the propagated of the vibration to the bonding portion between the lead portion 10b of the power terminal 10 and the bonding wire is significantly reduced or eliminated, so that the incidence of conduction defects is significantly suppressed in the semiconductor device according to the present embodiment.

Furthermore, as with the first embodiment hereof the tip of the folded portion 10c of the power terminals 10 for the drain electrode and the source electrode extend into the space between the busbar mounting portion 10a and the nuts 13a and 13b, so that the folded portion 10c enables the busbar mounting portion 10 to function as a lock washer. In other words, the tightening between the bolt and the nut 3a is strengthened by the bias of the folded portion 10c in a direction perpendicular to the top of casing 22. As a result, even when vibration is transmitted to the power terminal 10 from the busbar, in the semiconductor device according to the present embodiment, the occurrence of loosening between the bolt and the nuts 13a and 13b can be reduced in the busbar mounting portion 10a of the power terminal 10. Therefore, the occurrence of conduction defect occurring between the power terminal 10 and the busbar is suppressed.

A semiconductor device according to the present embodiment that has two semiconductor elements 11 has been explained; however, the configuration is not limited to the previous description. It is also possible to have a single, or multiple semiconductor elements electrically connected in series using this configuration.

### Third Embodiment

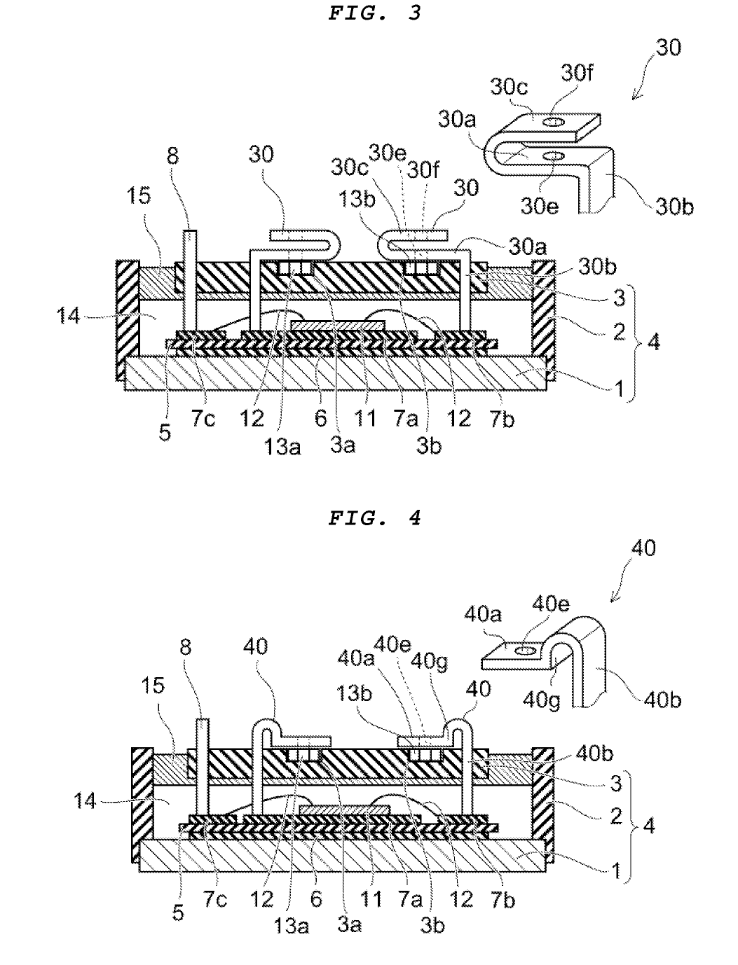

A semiconductor device according to a third embodiment will be explained using FIG. 3. FIG. 3 is a schematic cross-sectional view of the semiconductor device according to the third embodiment. The drawing shows an enlarged schematic cross-sectional view of a substantial portion of a power terminal 30. The same elements as that of the first embodiment will use the same reference numbers or symbols, so a duplicative explanation will be omitted. The explanation will be given mainly on the differences of the embodiment as compared to the first embodiment.

As shown in FIG. 3, in the semiconductor device according to the present embodiment, the busbar mounting portion 10a of the power terminal 30 for the drain electrode has one end formed as a folded back u-shaped portion 30c formed at the end thereof extending from the package at the opposite side thereof from the heat sink 1, and a second end, extending inwardly of the package to affect electrical connection to the semiconductor device 11. The u-shaped portion forms a busbar mounting portion 30a, which extends generally perpendicular to the upper end of a lead portion 30b extending from the package. In other words, the power terminal 30 is folded toward the interior of the perimeter of casing 2 of the resin package 4, and then back in the direction of the perimeter of the casing 2. The lead portion 30b passes through the terminal holder 3 and connects with the busbar mounting portion 30a provided directly over of the terminal holder 3, the lead portion 30b passing through the terminal holder 3.

The busbar mounting portion 30a is provided with a hole 30e for a bolt to pass therethrough, and the center of this hole 30e is aligned on the same line in a direction perpendicular to the heat sink 1 with the center of the hole of the nut 13a provided inside of the recess 3a on top of the surface of the terminal holder 3. The diameter of the hole 30e of the busbar mounting portion 30a is at least smaller than the outer diameter of the nut 13a and larger than the diameter of the hole of the nut 13a.

The folded portion 30c of the busbar mounting portion 30a extends so as to face the busbar mounting portion 30a above the hole 30e of the busbar mounting portion 30a. The folded portion 30c is provided with the hole 30f for a busbar attaching bolt to pass through having the same diameter as the hole 30e of the busbar mounting portion 30a. The center of the hole 30f is aligned on the same line in a direction perpendicular to the surface of the heat sink 1 with the center of the hole 30e of the busbar mounting portion 30a.

In the semiconductor device of the present embodiment, the power terminal 30 for the drain electrode has the busbar mounting portion 30a, the folded portion 30c, and the lead portion 30b, similar to the power terminal 10 according to the first embodiment. However, the configuration of the busbar mounting portion 30a and the folded portion 30c of the power terminal 30 for the drain electrode according to the present embodiment is different from the busbar mounting portion 10a and the folded portions 10c and 10d of the power terminal 10 according to the first embodiment, as the busbar mounting portion 30a is supported at only one end or side thereof. In the semiconductor device of the present embodiment, when the power terminal 30 for the drain electrode and the busbar are connected together by the bolt, the bolt passes through the hole of the busbar, the hole 10e of the busbar mounting portion 30a of the power terminal 30 for the drain and the hole 30f of the folded portion 30c, and is tightened into the nut 13a. In this way, similar to the power terminal 10 for the drain electrode according to the first embodiment, the power terminal 30 for the drain electrode according to the present embodiment has the folded portion 30c functioning as a spring structure. The folded portion 30c provides a bias in a direction perpendicular to, and away from, the terminal holder 3. Furthermore, in the semiconductor device according to the present embodiment, the folded portion 30c of the power terminal 30 for the drain electrode enables the busbar mounting portion 30 to function as a lock washer, similarly to the semiconductor device according to the first embodiment.

In the semiconductor device according to the present embodiment, as with the semiconductor device according to the first embodiment, the power terminal 30 for the source electrode has the same configuration and functionality as the power terminal 30 for the drain electrode.

In the semiconductor device according to the present embodiment, similarly to the semiconductor device according to the first embodiment, the power terminals 30 for the drain electrode and the source electrode have the folded portion 30c functioning as the spring by the configuration including the busbar mounting portion 30a, the lead portion 30b, and the folded portion 30c, but without a second folded portion. For this reason, the vibration that is propagated to the power terminal 30 from the busbar is mitigated or eliminated by the spring action of the folded portion 30c. As a result, the amount of vibration transmitted to the soldered portion between the lead portion 30b of the power terminal 30 and the metal wiring patterns 7a and 7b on top of the insulating substrate 5 is attenuated or eliminated, so that a conduction defect occurring from a failure of a solder bond of a terminal within the package is significantly reduced in the semiconductor device according to the present embodiment.

Furthermore, the diameter of the hole 30e of the busbar mounting portion 30a of the power terminal 30 is smaller than the outer diameters of the nuts 13a and 13b and larger than the diameter of the holes of the nuts 13a and 13b, so that the folded portion 10c enables the busbar mounting portion to function as a lock washer. In other words, the maintenance of a tight connection of the bolt into the nuts 3a and 3b can be enhanced by the bias, of the folded portion 30c, in a direction perpendicular to the heat sink 1. As a result, even when vibration is transmitted to the power terminal 30 from the busbar, the loosening of the connection between the bolt and the nuts 13a and 13b can be suppressed in the busbar mounting portion 30a of the power terminal 30 in the semiconductor device according to the present embodiment. Therefore, the occurrence of conduction defects between the power terminal 30 and the busbar can be suppressed.

### Fourth Embodiment

A semiconductor device according to the fourth embodiment will be explained using FIG. 4. FIG. 4 is a schematic cross-sectional view of the semiconductor device according to the fourth embodiment. The same configuration as that in the first embodiment will use the same reference numbers or symbols, so the duplicative explanation will be omitted. The explanation will be given mainly on the differences as compared to the first embodiment.

As shown in FIG. 4, in the semiconductor device according to the present embodiment, similarly to the semiconductor device according to the first embodiment, includes a power terminal 40 of the drain electrode configured to include a busbar mounting portion 40a, a lead portion 40b, and a folded portion 40g.

In this embodiment, the lead portion 40b of the power terminal 40 for the drain electrode extends from the inside of the resin package 4 to the outside of the resin package 4, along a direction perpendicular to the heat sink 1 passing through the terminal holder 3. One end of the lead portion 40b is folded into a u-shaped folded portion 40g, and then is further folded to form a busbar mounting portion 40a extending over and against the outer surface of terminal holder 3. The end of lead portion 40b extending into resin package 4, is electrically connected by solder to the metal wiring pattern 7a on top of the insulating substrate on which the semiconductor element 11 is installed.

The busbar mounting portion 40a is provided directly on the top surface of the terminal holder 3 so as to overlie and cover the nut 13a provided inside of the recess 3a on the top surface, which is at the opposite side of the heat sink of the terminal holder 3. One end of the busbar mounting portion 40a is connected to the folded portion 40g provided on the one end of the lead portion 40b. The busbar mounting portion 40a is provided with a hole 40e for a bolt to pass therethrough. The center of the hole 40e of the busbar mounting portion 40a is aligned on the same line as the center of the hole of the nut 13a in a direction perpendicular to terminal holder 3.

In the semiconductor device according to the present embodiment, the power terminal 40 for the drain electrode is different from the power terminal 10 for the drain electrode in the semiconductor device according to the first embodiment according to the previously mention points. The power terminal 40 for the drain electrode according to the present embodiment has the busbar mounting portion 40a supported by the lead portion 40b via the folded portion 40g of the lead portion 40b. As a result, the u-shaped folded portion 40g functions as the spring structure, so that the busbar mounting portion 40a may have a bias in a direction perpendicular to, and away from the heat sink 1. In this way, similarly to the power terminal 10 for the drain electrode according to the first embodiment, the power terminal 40 for the drain electrode according to the present embodiment can mitigate the vibration or stress from the busbar connected by the bolt and nut 13a.

The power terminal 40 for the source electrode according to the present embodiment also has the same configuration and function as the power terminal 40 for the drain electrode. With regard to others than stated above, the semiconductor device according to the present embodiment has the same configuration as the semiconductor device according to the first embodiment.

In the semiconductor device according to the present embodiment, similarly to the semiconductor device according to the first embodiment, the power terminal 40 for the drain electrode and the source electrode has the folded portion 40g functioning as the spring structure by the configuration including the busbar mounting portion 40a, the lead portion 40b, and the folded portion 40g. For this reason, the vibration that is propagated to the power terminal 40 from the busbar is mitigated by the folded portion 40g. As a result, the amount of vibration transmitted to the solder portion of the lead portion 40b of the power terminal 40 and the metal wiring patterns 7a and 7b on top of the insulating substrate 5 are eliminated or reduced, so that the incidence of a conduction defect can be significantly suppressed even in the semiconductor device according to the present embodiment.

While certain embodiments have been described, these embodiments have been presented by way of example only, and they are not intended to limit the scope of the inventions. Indeed, the novel embodiments described herein maybe embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a package having a heat sink, a case surrounding a perimeter of the heat sink, and a top plate separated from the heat sink and positioned overlying the heat sink;
a semiconductor element provided on the heat sink through an intervening insulating substrate;
a sealant in the package; and
a metal terminal extended from within the package to the exterior of the package and electrically connected to the semiconductor element at a location within the package,
wherein the metal terminal includes:
a busbar mounting portion comprising a planar body extending over the surface of the top plate and provided with an aperture for a fastener to pass therethrough,
a lead portion extending through the top plate and connected to the busbar mounting portion, and
a spring structure, biasable in a direction perpendicular to the surface of the top plate, in the busbar mounting portion.

2. The semiconductor device according to claim 1, wherein
the spring structure is a folded portion extending between the busbar mounting portion and the lead portion.

3. The semiconductor device according to claim 2, wherein
the metal terminal further includes a second spring structure formed of a folded portion of the terminal located at an end of the busbar mounting portion opposed to the connection of spring structure with busbar mounting portion.

4. The semiconductor device according to claim 2, wherein
the busbar mounting portion is spaced from the top plate by the spring structure.

5. The semiconductor device according to claim 2, further comprising:
an attachment member located within a recess provided on a surface of the top plate;
wherein the center of the hole of the busbar mounting portion is aligned with the center of a hole of the attachment member in a direction perpendicular to the surface of the top plate, and a portion of the folded portion extends into a space between the attachment portion and the busbar mounting portion.

6. The semiconductor device according to claim 2, wherein
the busbar mounting portion is supported over the top plate case by the spring structure.

7. The semiconductor device according to claim 6, further comprising:
an attachment member having a hole therein and located within recesses provided on the top surface of the top plate,
wherein the center of the hole of the busbar mounting portion is aligned on the same line with the center of the hole of the attachment member in a direction perpendicular to the surface of the top plate, and a portion of the second folded portion extends into the space between the nut and the busbar mounting portion.

8. The semiconductor device according to claim 2, wherein
the folded portion is folded back in the direction of the tope plate, and
the busbar mounting portion overlies and contacts the top plate and is connected to the lead portion passing through the resin top plate through the folded portion.

9. The semiconductor device according to claim 8, wherein
the busbar mounting portion is provided with a hole.

10. The semiconductor device according to claim 9, further comprising:
a fastener location in a recess provided on the surface of top plate,
wherein the center of the hole of the busbar mounting portion is aligned on the same line with the center of the hole of the nut in a direction perpendicular to the surface of the top plate.

11. A method of connecting a package terminal to a busbar, comprising:
extending a portion of the terminal inwardly of the package and into electrical contact with a conductor within the package, and
forming a portion of the terminal extending from the packages as connection portion and an isolation portion.

12. The method of claim 11, including the step of configuring the isolation portion as a u-shaped bend in the body of the terminal.

13. The method of claim 12, further including the step of spacing the connecting portion from the surface of the package with the isolation portion.

14. The method of claim 13, further including the steps of:
providing a hole through the connecting portion;
providing a fastener anchor within the body of the package and aligned with the hole;
extending a fastener through the hole and into the anchor and thereby moving the connection portion with respect to the body of the package; and
providing a bias on the connection portion with the isolation portion in a direction opposed to the body of the package.

15. The method of claim 11, further including the step of:
providing a plate and extending the portion of the terminal extending into the package through the plate; and
positioning a sealant between the plate and the conductor within the package.

16. A packaged semiconductor device having an electrical connection to the semiconductor device extending therefrom, comprising:
a terminal forming a pathway for the electrical connection, formed of a single piece of a conductive material, and having a first portion extending inwardly of the packaged semiconductor device; and
a second portion disposed exteriorly to the packaged semiconductor device, and a flexible portion extending between the first and the second portions.

17. The packaged semiconductor of claim 16, further including:
an aperture extending through the second portion;
a fastener recipient positioned within the package; and
a fastener extending through the aperture and into the recipient.

18. The packaged semiconductor of claim 17, wherein the fastener secures a conductor to the second portion of the terminal, and supplies a force to induce a bias in the connecting portion.

19. The packaged semiconductor of claim 16, wherein the second portion is spaced from the exterior of the package and supported by the flexible portion.

20. The packaged semiconductor of claim 16, wherein the second portion directly contacts the package of the packaged semiconductor device.
